(19) United States
(12) Patent Application Publication
(10) Pub. No.: US 2007/0059440 A1
(43) Pub. Date: Mar. 15, 2007

(54) Method for manufacturing plasma display panel

(76) Inventors: Dae Hyun Park, Yongin-si (KR); Kyung Ku Kim, Anyang-si (KR); Byung Hwa Seo, Seoul (KR); Min Soo Park, Seoul (KR); Won Seok Jeon, Suwon-si (KR); Dong Oh Shin, Gwacheon-si (KR); Deok Hai Park, Joong-gu (KR); Hong Cheol Lee, Seoul (KR); Je Seok Kim, Anyangi-si (KR); Byung Gil Ryu, Seoul (KR)

Correspondence Address: FLESHNER & KIM, LLP, P.O. BOX 221200, CHANTILLY, VA, 20153, US

(21) Appl. No.: 11/519,203

(22) Filed: Sep. 12, 2006

(30) Foreign Application Priority Data
Sep. 13, 2005 (KR) 10- 2005-0085096
Oct. 5, 2005 (KR) 10-2005-0093572

(51) Int. Cl. H05K 3/00; B05D 5/12; C23C 28/00

(52) U.S. Cl. 427/98.4; 427/428.2

(57) ABSTRACT

A method for manufacturing a plasma display panel is disclosed. The plasma display panel manufacturing method includes forming an electrode material on a dielectric sheet, and transcribing the dielectric sheet and electrode material on a substrate simultaneously.

This application claims the benefit of the Korean Patent Application Nos. P 2005-0085096 filed on Sep. 13, 2005, P 2005-0093572 filed on Oct. 5, 2005 which is hereby incorporated by reference as if fully set forth herein.

### BACKGROUND OF THE INVENTION

1. Field of the Invention

The present invention relates to a plasma display panel, and more particularly, to a method for forming electrodes of a plasma display panel.

2. Discussion of the Related Art

Generally, a plasma display panel includes upper and lower panels and barrier ribs formed between the upper and lower panels, and the barrier ribs serve to divide electric discharge cells from one another. Each discharge cell is filled with a primary electric discharge gas, such as neon, helium, mixed gas of neon and helium, or the like, and an inert gas containing a small amount of xenon. If an electric discharge occurs by a high-frequency voltage, the inert gas generates vacuum ultraviolet rays to excite phosphors between the barrier ribs, thereby realizing the formation of an image using light emitted from the phosphors. The plasma display panel having the above described configuration is thin and light, and therefore, is highlighted as a next generation display device.

FIG. 1 is a perspective view schematically illustrating the configuration of a plasma display panel. As shown in FIG. 1, the plasma display panel includes an upper panel 100 and a lower panel 110, which are coupled parallel to each other with a predetermined distance therebetween. The upper panel 100 of the plasma display panel includes a plurality of sustain electrode pairs in which scan electrodes 102 and sustain electrodes 103 are formed in pairs. The plurality of sustain electrode pairs are arranged on an upper glass plate 101 serving as a display surface on which images are displayed. The lower panel 110 of the plasma display panel includes a plurality of address electrodes 113 arranged on a lower glass plate 111 to cross the plurality of sustain electrode pairs.

Barrier ribs 112 are arranged parallel to one another on the lower panel 110. The barrier ribs have a stripe form (or well form) for forming a plurality of discharge spaces, i.e. discharge cells. The plurality of address electrodes 113 are disposed parallel to the barrier ribs 112 and adapted to generate vacuum ultraviolet rays via implementation of an address discharge. R, G and B phosphors 114 are applied onto a top surface of the lower panel 110 and adapted to emit visible rays for displaying images during the address discharge. Also, a lower dielectric layer 115 for protecting the address electrodes 113 is formed between the address electrodes 113 and the phosphors 114.

The conventional plasma display panel having the above described configuration is basically manufactured through a glass manufacturing process, upper panel manufacturing process, lower panel manufacturing process, and assembling process. Also, a method for forming the electrodes of the plasma display panel is selected from among a screen printing method, photosensitive paste method, photo-etching method by sputtering, green sheet method, and the like.

However, the screen printing method has a difficulty in alignment because a printing process has to be repeatedly performed and also, cannot achieve high definition due to fluidity of a printing paste. The green sheet method is suitable to achieve a high definition electrode, but suffers from very high costs.

The photo-etching method by sputtering exhibits a complicated process and thus, is not preferable despite an advantage of high definition. Also, the photosensitive paste method has a problem in that electrodes may be peeled off unintentionally upon release of a photosensitive film pattern, or the photosensitive film pattern may fail to be released if an electrode paste remains on the photosensitive film pattern.

Conventionally, there is an attempt to form electrodes by an offset process. In the offset process, it is important to accurately coincide a bus electrode with a black matrix, i.e. align the bus electrode on the black matrix at a predetermined position. However, in the case of high definition panels, it is difficult to accurately coincide the bus electrode with the black matrix because the black matrix has an extremely fine pattern in response to a reduction in the size of each picture element cell. Moreover, poly siloxane rubber used as a blanket material tends to be swollen by solvent escaped from ink, and thus, the resulting blanket may lose initial offset characteristics thereof in accordance with change in surface characteristics. Accordingly, although it is general to exchange the blanket if the blanket is changed in surface characteristics after being used one or two times, this results in enormous cost loss. Also, the offset process has a necessity for additionally forming and firing dielectrics after firing the electrodes.

### SUMMARY OF THE INVENTION

Accordingly, the present invention is directed to a method for forming a plasma display panel that substantially obviates one or more problems due to limitations and disadvantages of the related art.

An object of the present invention is to provide a method for manufacturing a plasma display panel by an offset process in which a dielectric sheet and electrode material are directly formed on a surface of a roller without using a blanket, so as to be transferred onto a substrate.

Another object of the present invention is to provide a method for manufacturing a plasma display panel in which dielectrics and electrodes are fired together by a single process.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method for manufacturing a plasma display panel comprises: forming an electrode material on a dielectric sheet; and transcribing the dielectric sheet and electrode material on a substrate simultaneously.

In accordance with a further aspect of the present invention, there is provided a method for manufacturing a plasma display panel comprising: forming a bus electrode material and black matrix on a master mold in sequence; and

transcribing the bus electrode material and black matrix onto a substrate.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a perspective view illustrating an embodiment of a plasma display panel;

FIGS. 2A to 2D are views illustrating a method for manufacturing a plasma display panel according to a first embodiment of the present invention;

FIGS. 3A to 3D are views illustrating a method for manufacturing a plasma display panel according to a second embodiment of the present invention;

FIG. 4 is a flowchart of a method for manufacturing a plasma display panel according to a third embodiment of the present invention; and

FIGS. 5A to 5D are views illustrating the method for manufacturing a plasma display panel according to the third embodiment of the present invention.

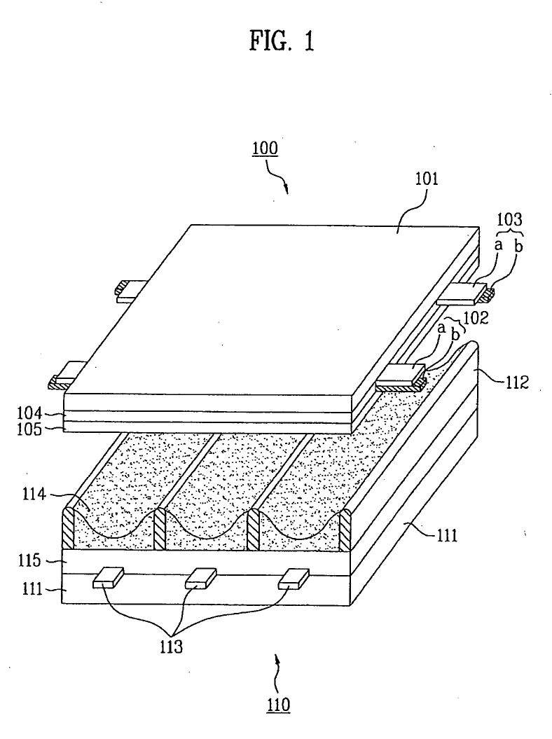

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

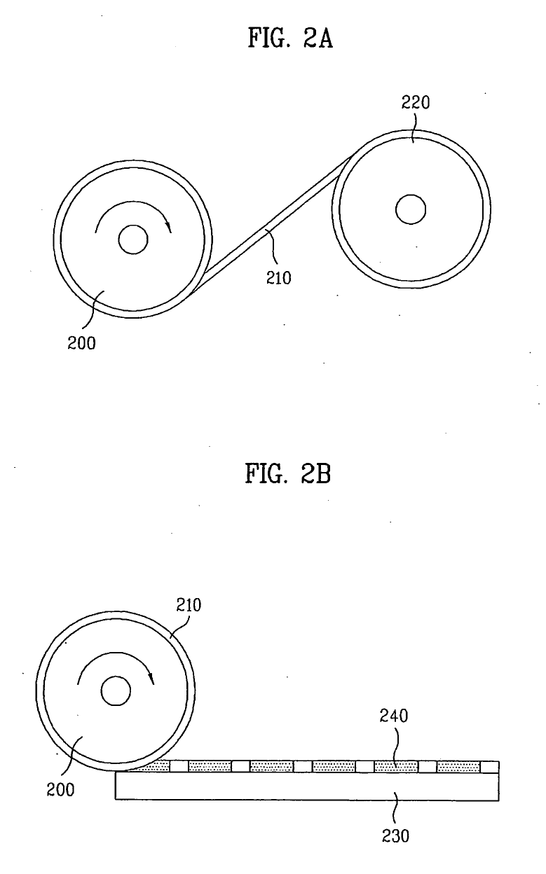

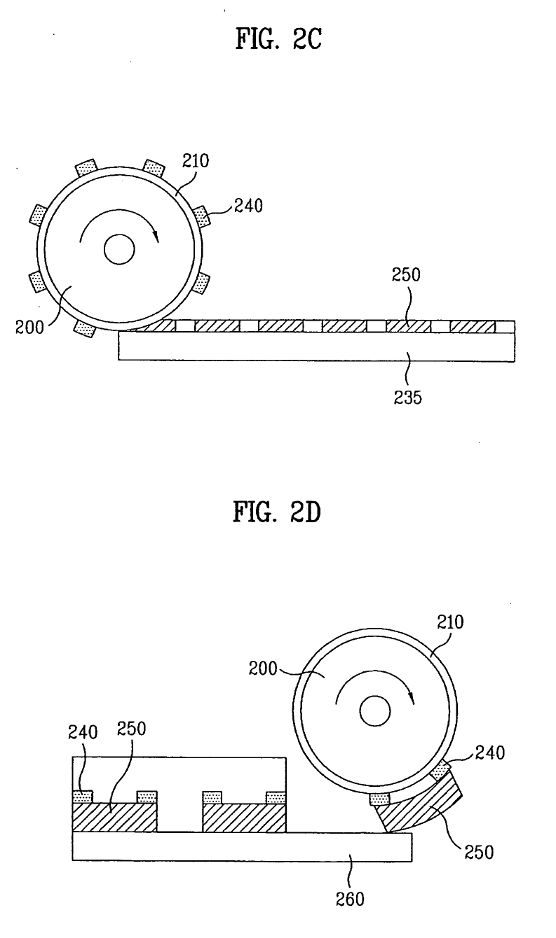

FIGS. 2A to 2D are views illustrating a method for manufacturing a plasma display panel according to a first embodiment of the present invention. Now, the first embodiment of the plasma display panel manufacturing method according to the present invention will be explained with reference to FIGS. 2A to 2D.

The first embodiment of the present invention has a feature in that a plasma display panel is formed by an offset process. More particularly, the present embodiment has a feature in that a dielectric sheet, rather than a blanket, is wound on a surface of a roller to allow an electrode material to be formed thereon, and in turn, the roller is rolled on a substrate to enable simultaneous formation of electrodes and dielectrics.

Considering the sequence of the method according to the present embodiment, first, a dielectric sheet 210 is wound on a surface of a roller 200. The roller 200 has no blanket on the surface thereof differently from the prior art, and therefore, the dielectric sheet 210 can be rolled around the roller 200 to come into direct contact with the surface of the roller 200. Preferably, the dielectric sheet 210, as shown in FIG. 2A, is previously wound on a lamination roller 220 prior to being wound on the roller 200. Specifically, the dielectric sheet 210 is prepared in such a manner that, after removing a protective film therefrom, the dielectric sheet formed on a base film is wound around the roller. Alternatively, the base film may be removed in a final step of the present method after laminating the dielectric sheet 210 on a substrate.

Next, an electrode material 240 is printed on a surface of the dielectric sheet 210 wound around the roller 200. Preferably, the electrode material 240 may be formed using a master mold 230. Specifically, if the master mold 230 is prepared in such a manner that recesses are formed in a surface of the master mold 230 by intaglio technique to have the same shape as that of desired electrodes, the electrode material 240 is injected into the recesses of the master mold 230. Subsequently, the electrode material 240, which was injected into the recesses of the master mold 230, is finished in shape by use of a cutting blade, to have the same shape as that of desired electrodes. Here, the electrode material may take the form of a paste containing silver, binder, solvent, dispersing agent, etc. Thereafter, if the roller 200, around which the dielectric sheet 210 was wound, is rolled on the master mold 230, the electrode material 240 is printed on the surface of the dielectric sheet 210 wound around the roller 200.

Then, if the roller 200 is rolled on a substrate, the dielectric sheet 210 and electrode material 240 are transcribed simultaneously on the substrate. Finally, if the electrodes and dielectrics are fired together, the formation of the electrodes and dielectrics is completed.

The above described simultaneous formation of the electrodes and dielectrics is applicable to a process for forming not only an upper panel, but also a lower panel of the plasma display panel. In the case of the upper panel, a black matrix can be formed simultaneously with the electrodes and dielectrics, and, in the case of the lower panel, barrier ribs can be formed simultaneously with the electrodes and dielectrics.

Now, an offset process for forming a black matrix bus electrodes as well as the dielectric sheet on the upper panel of the plasma display panel will be explained with reference to FIGS. 2C and 2D.

First, a black matrix 250 is printed on a surface of the electrode material 240 and dielectric sheet 210 wound around the roller 200. Preferably, the black matrix 250 is formed by use of a master mold 235. Here, it is noted that the dielectric sheet 210 is an upper panel dielectric sheet and the electrode material 240 is used to form bus electrodes. Both the dielectric sheet 210 and electrode material 240 are formed on the surface of the roller in the above described method.

Specifically, the master mold 235 is prepared in such a manner that recesses are formed in a surface of the master mold 235 by intaglio technique to have the same shape as that of a desired black matrix. Here, it is noted that the recesses of the master mold 235 have a different width from that of the recesses formed in the master mold 230 shown in FIG. 2b. After a material of the black matrix 250 is injected into the recesses of the master mold 235, the material of the black matrix 250 injected in the recesses is finished in shape by use of a cutting blade, to have the same shape as that of a desired black matrix. Preferably, the material of the black matrix 250 may take the form of a paste containing low fusion point glass, black pigment, etc. Subsequently, if the roller 200 is rolled on the master mold 235, the material of the black matrix 250 is released off from the master mold 235, to thereby be transferred onto the surface of the dielectric sheet 210 and electrode material 240 wound around the roller 200 (See FIG. 2C).

Thereafter, the roller 200, on which the dielectric sheet 210, electrode material 240, and black matrix 250 are formed in sequence, is rolled on a substrate 260. As such, the black matrix, bus electrodes and upper panel dielectrics are formed on the substrate 260 in sequence. Preferably, the substrate is a glass substrate, and transparent electrodes are formed on an upper surface of the glass substrate. Finally, if the upper panel dielectric sheet 210, bus electrodes 240, and black matrix 250 are fired simultaneously and a protective film is formed over the upper panel dielectric sheet 210, the formation of the upper panel of the plasma display panel is completed. It is noted that a base film has to be removed from the upper panel dielectric sheet 210 prior to forming the protective film as described above. The above firing process is performed at a high temperature of more than 500° C., and in the course of burning off the binder, the solvent may also be evaporated.

Hereinafter, the operational effects of the plasma display panel manufacturing method according to the first embodiment of the present invention will be described.

In summary, firstly, the upper panel dielectric sheet is directly formed on the surface of the roller in the offset process without using a blanket, and secondly, the bus electrodes and black matrix are formed on the upper panel dielectric sheet, and finally, the black matrix, bus electrodes and upper panel dielectric sheet can be formed on the substrate simultaneously. With the present embodiment, the materials used to form the bus electrodes and black matrix does not come into direct contact with a blanket, and this is advantageous to increase the freedom of material choice.

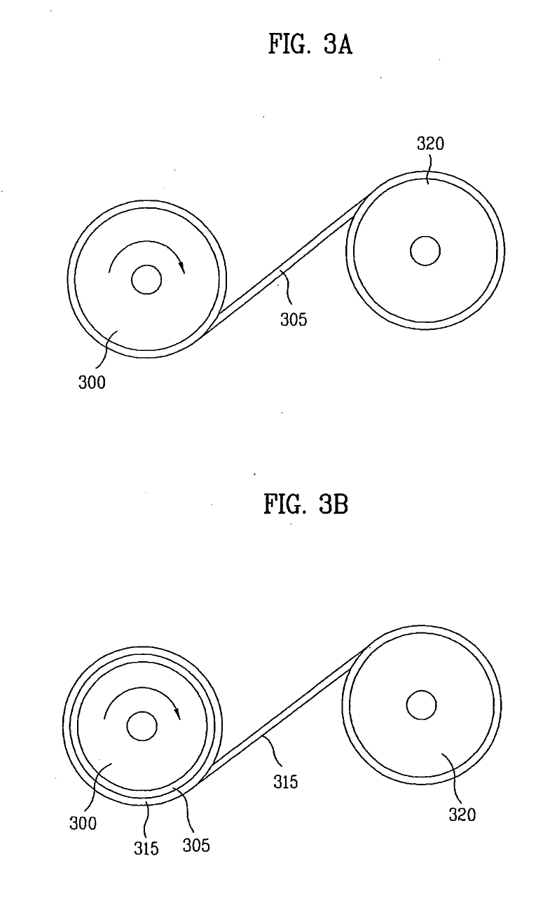

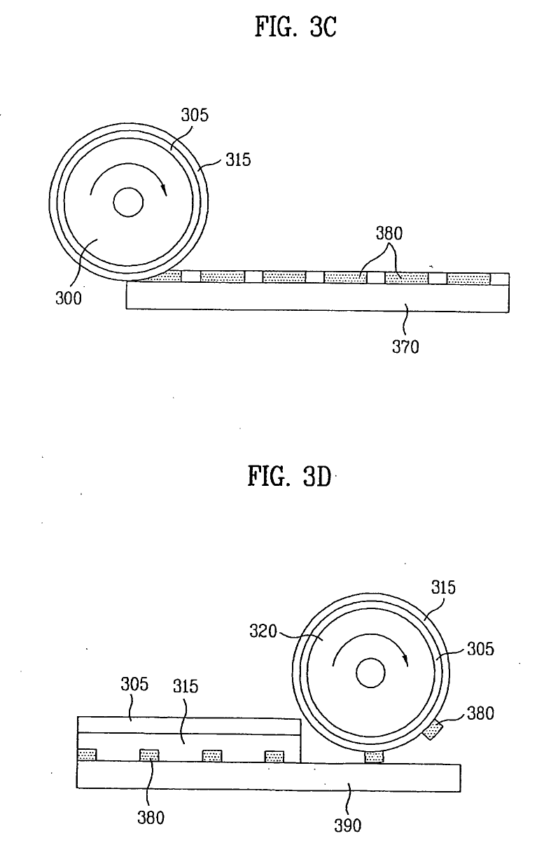

Now, a second embodiment of the plasma display panel manufacturing method according to the present invention will be explained with reference to FIGS. 3A to 3D.

The second embodiment of the present invention has a feature in that address electrodes are formed on a lower panel of the plasma display panel by an offset process. More particularly, differently from the above described first embodiment, the dielectric sheet is used to form a lower panel dielectric sheet, and the electrode material is used to form the address electrodes. Accordingly, although the present embodiment is basically similar to the above described first embodiment, there is a difference in that barrier ribs are simultaneously formed with the lower panel dielectrics and address electrodes as will be described hereinafter.

Considering the sequence of the method according to the present embodiment, first, a barrier rib sheet 305 is wound around a roller 300. The roller 300 has no blanket on a surface thereof differently from the prior art, and therefore, the barrier rib sheet 305 can be rolled around the roller 300 to come into direct contact with the surface of the roller 300. The barrier rib sheet 305 may be wound around the roller 300 as it is released from a lamination roller 320 as shown in FIG. 3A, so as to be subjected later to a lamination method. Specifically, the barrier rib sheet 305 is prepared in such a manner that, after removing a protective film therefrom, the barrier rib sheet formed on a base film is laminated. Alternatively, the base film may be removed in a final step of the present method after laminating the barrier rib sheet 305 on a substrate.

Next, as shown in FIG. 3B, a lower panel dielectric sheet 315 is formed on a surface of the barrier rib sheet 305 wound around the roller 300. In this case, a lamination method may be used.

Then, an electrode material, more particularly, address electrode material 380, is transferred onto a surface of the lower panel dielectric sheet 315 formed on the barrier rib sheet 305. Here, the address electrode material 380 may be transferred by use of a master mold 370. More specifically, the master mold 370 is prepared in such a manner that recesses are formed in a surface of the master mold 370 by intaglio technique to have the same shape as that of desired address electrodes. It is noted that the recesses of the master mold 370 have a different width, etc. from that of the recesses formed in the master mold of the above described first embodiment.

After an address electrode material 380 for forming address electrodes on the surface of the master mold 370 is injected into the recesses of the master mold 370, the address electrode material 380 injected into the recesses of the master mold 370 is finished in shape by use of a cutting blade, to have the same shape as that of desired address electrodes. Here, the address electrode material 380 may take the form of a paste containing silver, binder, solvent, dispersing agent, etc. Thereafter, if the roller 300, around which the barrier rib sheet 305 and lower panel dielectric sheet 315 are wound, is rolled on the master mold 370 as shown in FIG. 3C, the electrode material 380 is released from the master mold 370, and is printed on the surface of the dielectric sheet 210 wound around the roller 200.

Finally, as shown in FIG. 3D, the roller 300, on which the barrier rib sheet 305, lower panel dielectric sheet 315, and electrode material 380 are formed in sequence, is rolled on a substrate 390. Thereby, the address electrode material 380, lower panel dielectric sheet 315, and barrier rib sheet 305 are transcribed on the substrate in this sequence. If the resulting address electrodes, lower panel dielectrics, and barrier ribs are fired simultaneously after finishing the barrier rib sheet 305 to have a desired barrier rib shape, the formation of the lower panel of the plasma display panel is completed. The above firing process is performed at a high temperature of more than 500° C., and in the course of burning off the binder, the solvent also may be evaporated.

The operational effects of the plasma display panel manufacturing method according to the second embodiment of the present invention are basically similar to that of the first embodiment. That is, firstly, the barrier rib sheet, lower panel dielectrics, and address electrode material are directly formed on the surface of the roller without using a blanket, and secondly, the address electrodes, lower panel dielectrics, and barrier ribs may be formed on the substrate simultaneously. With the present embodiment, the material used to form the address electrodes, more particularly, ink does not come into direct contact with a blanket, and this is advantageous to increase the freedom of material choice.

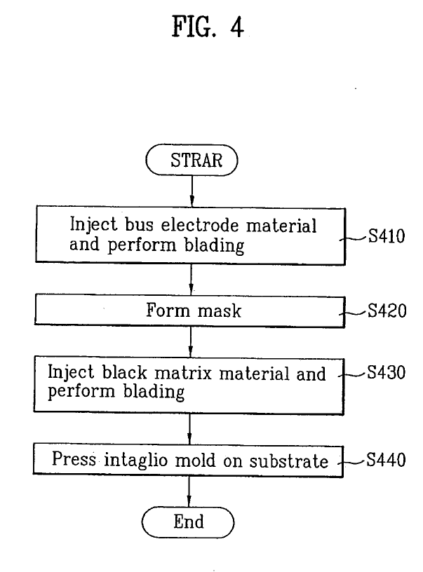

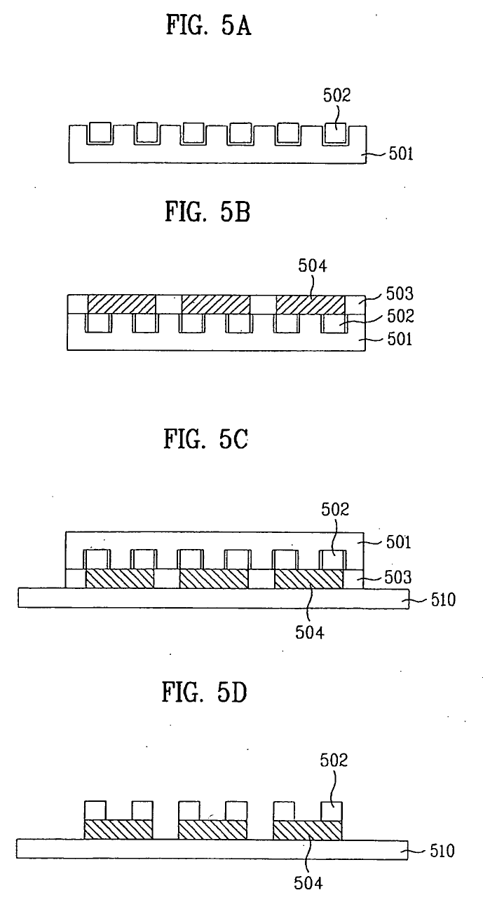

FIG. 4 is a flowchart of a method for manufacturing a plasma display panel according to a third embodiment of the present invention, and FIGS. 5A to 5D are views illustrating the plasma display panel manufacturing method according to the third embodiment of the present invention. Now, the third embodiment of the method for manufacturing a plasma display panel according to the present invention will be explained with reference to FIGS. 4 to 5D.

The third embodiment of the present invention has a feature in that a bus electrode material and black matrix material are first formed on a mater mold having recesses formed by intaglio technique (hereinafter, referred to as an intaglio mold), and then, the intaglio mold is pressed on a substrate, to form a black matrix and bus electrodes simultaneously. Another feature of the present embodiment is that a shadow mask is used when the black matrix material is formed on the intaglio mold.

Considering the sequence of the method according to the present embodiment, first, a bus electrode material and black matrix material are formed in an intaglio mold. To form the bus electrode material, as shown in FIG. 5A, an intaglio mold 501, which has recesses formed by a predetermined distance to have the same shape as that of desired bus electrodes, is prepared, such that a bus electrode material 502 is injected into the recesses. Preferably, the bus electrode material 502 contains silver, and is subjected to a blading treatment for the insulation of composites. In this way, the bus electrode material 502 is filled in the recesses of the intaglio mold 501 (S410).

Next, as shown in FIG. 5B, a shadow mask 503 is located on the intaglio mold 501, in which the bus electrode material 502 was injected, to form a black matrix (S420). Then, a black matrix material 504 is injected into patterned portions of the shadow mask 503, and is subjected to a blading treatment for the isolation of respective bits of the black matrix material 504 injected into respective patterned portions (S430). In this way, the bus electrode material 502 and black matrix material 504 are formed on the intaglio mold 501.

Subsequently, as shown in FIG. 5C, the intaglio mold 501, on which the bus electrode material 502 and black matrix material 504 are formed, is pressed onto a substrate 510 (S440). Specifically, the intaglio mold 501 is pressed onto the substrate 510 in such a manner that an assembly of the bus electrode material 502 and black matrix material 504 comes into contact with the substrate 510, so as to allow the bus electrode material 502 and black matrix material 504 to be printed, i.e. transcribed, onto the substrate 510 simultaneously. Here, the direction of printing should be noted because the black matrix material 540 has to come into contact with a surface of the substrate 510.

Thereafter, as shown in FIG. 5D, the intaglio mold 501 and the black matrix forming shadow mask 503 attached to the intaglio mold 501 are separated from the substrate 510, to leave the bus electrode material 502 and black matrix material 504 on the substrate 510. Finally, if the bus electrode material 502 is fired, and upper panel dielectrics and protective film are formed, the formation of the upper panel of the plasma display panel is completed.

With the above described method, the bus electrodes 502 and black matrix 504 are formed on the substrate 510. In conclusion, the black matrix and bus electrodes can be simultaneously formed via a single printing process, and this is advantageous to simplify the overall manufacturing process of the upper panel of the plasma display panel.

In the above described embodiment, furthermore, if any elastic material, such as poly-dimethyl-siloxane, may be used to construct the intaglio mold and black matrix shadow mask, the intaglio mold is flexible to facilitate an efficient printing operation, and this results in an improvement in transcription characteristics.

In the above described embodiments of the plasma display panel manufacturing method, other constituent elements except for the electrode forming method are same as the prior art.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for manufacturing a plasma display panel comprising:
forming an electrode material on a dielectric sheet; and
transcribing the dielectric sheet and electrode material on a substrate simultaneously.

2. The method according to claim 1, further comprising:
firing the dielectric sheet and electrode material formed on the substrate.

3. The method according to claim 1,
wherein the dielectric sheet and electrode material are formed on a surface of a roller, and
wherein the formation of the electrode material on the dielectric sheet comprises:
winding the dielectric sheet on the surface of the roller; and
transferring the electrode material onto a surface of the dielectric sheet.

4. The method according to claim 3, wherein the transfer of the electrode material comprises:
injecting the electrode material into recesses formed in a master mold; and
rolling the roller on the master mold.

5. The method according to claim 3, wherein the electrode material is a bus electrode material.

6. The method according to claim 5, further comprising:
transferring a black matrix onto a surface of the electrode material, and
wherein the transcription of the dielectric sheet and electrode material comprises:
rolling the roller, on which the dielectric sheet, electrode material, and black matrix are formed in sequence, on the substrate, to form dielectrics, electrodes, and a black matrix simultaneously on the substrate.

7. The method according to claim 6, wherein the transfer of the black matrix comprises:
injecting the black matrix into recesses formed in a master mold; and
rolling the roller on the master mold.

8. The method according to claim 3, wherein the electrode material is an address electrode material.

9. The method according to claim 8, wherein the dielectric sheet and electrode material are formed on a surface of a barrier rib sheet that is formed on the surface of the roller.

10. A method for manufacturing a plasma display panel comprising:
forming a bus electrode material and black matrix on a master mold in sequence; and
transcribing the bus electrode material and black matrix onto a substrate.

11. The method according to claim 8, wherein the formation of the bus electrode material and black matrix on the master mold comprises:
injecting the bus electrode material into the master mold; and
forming the black matrix on the mater mold.

12. The method according to claim 11, wherein the injection of the bus electrode material comprises:
injecting the bus electrode material into recesses of the master mold, the recesses being spaced apart from one another by the same distance as that of bus electrodes to be formed on the master mold; and
blading the injected bus electrode material.

13. The method according to claim 11, wherein the formation of the black matrix on the master mold comprises:
positioning a mask on the master mold in which the bus electrode material is injected;
injecting the black matrix material; and
blading the injected black matrix material.

14. The method according to claim 13, wherein at least one of the master mold and mask is made of an elastic material capable of increasing flexibility for transcription.

15. The method according to claim 10, wherein the transcription of the bus electrode material and the black matrix comprises:
positioning the master mold on which the bus electrode material and black matrix are formed in sequence, such that the black matrix comes into contact with the substrate, and pressing the mater mold; and
separating the master mold and a mask from the substrate.

16. The method according to claim 15, wherein the press of the master mold comprises:
bending the master mold to come into close contact with the substrate; and
printing the black matrix and bus electrode material, which are formed on the master mold, on the substrate.
